(19) United States
(12) Patent Application Publication
(10) Pub. No.: US 2008/0089035 A1
(43) Pub. Date: Apr. 17, 2008

(54) COMPUTER HAVING CASE WITH DUSTPROOF STRUCTURE

(75) Inventors: ZHEN-XING YE, Shenzhen (CN); XIAO-ZHU CHEN, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/611,157

(22) Filed: Dec. 15, 2006

(30) Foreign Application Priority Data
Oct. 11, 2006 (CN) 200610200980.5

(51) Int. Cl. H05K 7/00

(52) U.S. Cl. 361/724; 361/679; 312/223.2

(57) ABSTRACT

A computer includes a front panel defining an opening, and a door mounted to the front panel in alignment with the opening in the front panel. The door includes a frame, a plurality of slats rotatably mounted to the frame, a motor mechanically connectable to the slats, and a controlling module controlling the motor to drive the slats to rotate for exposing or covering the opening in the front panel.

### BACKGROUND OF THE INVENTION

1. Field of the Invention

The invention relates to computers. In particular, the present invention relates to a computer, which includes a computer case having a dustproof structure.

2. Description of related art

A conventional computer case usually has a plurality of through holes defined in a front panel thereof. The through holes are used for dissipating heat produced by a plurality of computer components in the computer case. However, the through holes become an access for dust entering into the computer case, especially after the computer is powered off. The accumulated dust may harmnormal operation of the computer.

What is needed is a computer case which includes a dustproof structure.

### SUMMARY OF THE INVENTION

An exemplary computer includes a front panel defining an opening, and a door mounted to the front panel in alignment with the opening. The door includes a frame fixed to the front panel, a plurality of slats rotatably mounted to the frame, a motor mechanically connectable to the slats, and a controlling module controlling the motor to drive the slats to rotate for exposing or covering the opening in the front panel.

Other advantages and novel features will become more apparent from the following detailed description when taken in conjunction with the accompanying drawing, in which:

### BRIEF DESCRIPTION OF THE DRAWINGS

FIG. 1 is an exploded, isometric view of a motor-driven door for being mounted in a computer in accordance with a preferred embodiment of the present invention, the motor-driven door having five slats;

FIG. 2 is an assembled view of FIG. 1;

FIG. 3 is an isometric view of the computer, with the motor-driven door mounted in the computer and the slats in an open position; and

FIG. 4 is similar to FIG. 3, but showing the slats in a closed position.

### DETAILED DESCRIPTION OF THE INVENTION

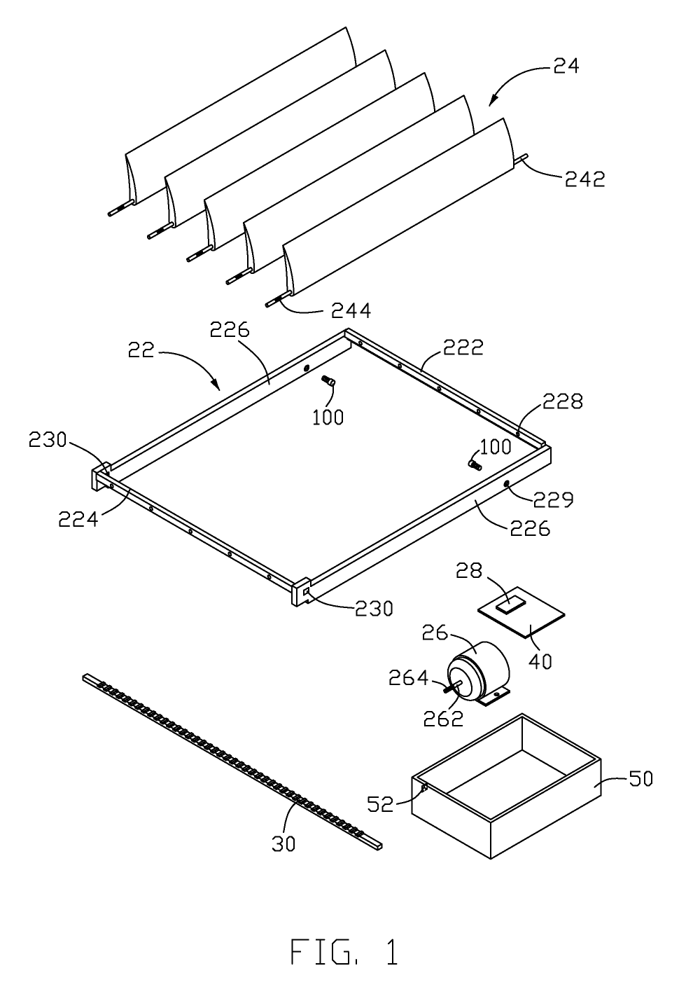

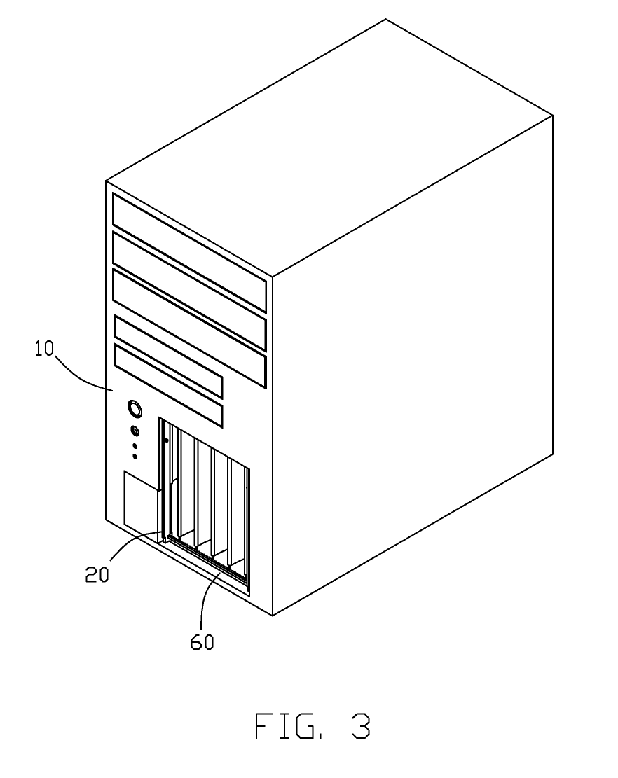

Referring to FIGS. 1 and 3 , a computer in accordance with a preferred embodiment of the present invention includes a computer case having a front panel 10, and a motor-driven door 20 mounted on a lower portion of the front panel 10.

The motor-driven door 20 includes a frame 22, five slats 24 rotatably mounted on the frame 22, a motor 26, a controlling board 40 having a controlling module 28 installed thereon, a rack 30, and a housing 50 receiving the motor 26 and the controlling module 28.

The frame 22 includes an upper wall 222, a lower wall 224 parallel to the upper wall 222, and two sidewalls 226 connecting the upper wall 222 with the lower wall 224. Five mounting holes 228 are defined in the upper wall 222 and the lower wall 224 respectively. A locking hole 229 and a stop hole 230 are defined in each sidewall 226. A locating hole 52 is defined in a wall of the housing 50, corresponding to the stop holes 230 of one of the sidewalls 226.

Each slat 24 includes two shafts 242 extending from opposite sides thereof, a first gear 244 is set on one of the shafts 242, the first gear 244 can be a plurality of teeth provided on one of the two shafts 242.

The motor 26 includes a rotating shaft 262 with a second gear 264 set thereon, the second gear 264 can be a plurality of teeth provided on the rotating shaft 262. The motor 26 is electrically connected to the controlling module 28 and the shaft 262 can rotate in opposite directions via control of the controlling module 28.

The controlling module 28 is mounted on the controlling board 40. The controlling board 40 is connected to a motherboard of the computer via a cable (not shown) for receiving control information from the motherboard. In this embodiment, the controlling module 28 is electrically connected to a system management bus (SMBUS) port of the motherboard for receiving control information about the computer being on or off.

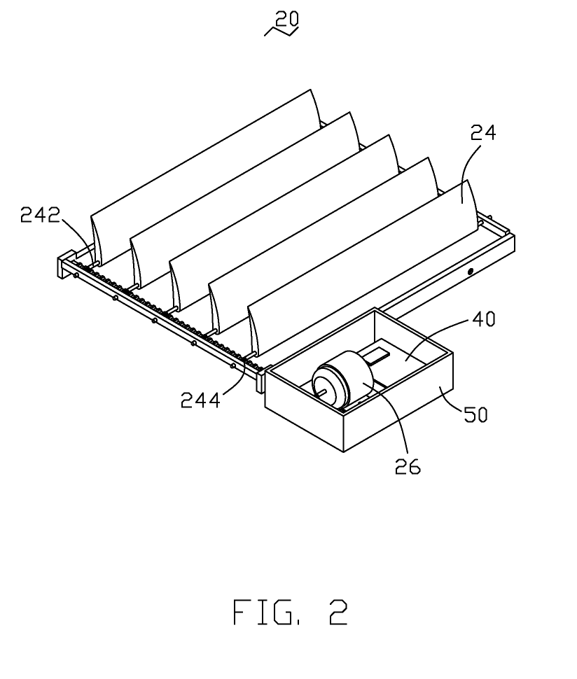

Referring also to FIG. 2, in assembly, the motor 26 and the controlling board 40 are mounted in the housing 50. Each slat 24 is rotatably attached in the frame 22, with the shafts 242 extending through corresponding mounting holes 228 of the upper wall 222 and the lower wall 224. The first gear 244 of each slat 242 is positioned adjacent the lower wall 224.

The rack 30 which forms thereon a plurality of teeth or notches meshable with the first gear 244 and the second gear 264 extends through the stop holes 230 of the sidewalls 226, and the locating hole 52 of the housing 50. The first gears 244 of the slats 24 and the second gear 264 of the motor 26 are meshed with the rack 30. The stop holes 230 of the sidewalls 226 and the locating hole 52 of the housing 50 are defined for guiding the rack 30 to move therethrough and preventing the rack 30 from disengaging from the first gears 244 and the second gear 264.

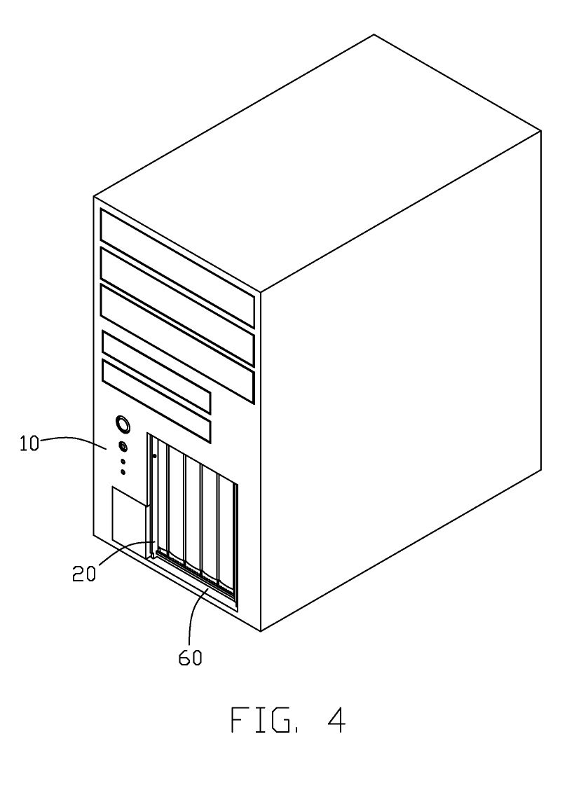

Referring also to FIGS. 3 and 4, an opening 60 is defined in the lower portion of the front panel 10. A mounting hole (not shown) is defined in each opposite sidewall adjoining the opening 60, corresponding to the locking holes 229 of the sidewalls 226 of the frame 22. The motor-driven door 20 is mounted to the front panel 10 by fasteners, such as two screws 100, extending through the corresponding locking holes 229 of the frame 22 of the motor-driven door 20, to engage in the corresponding mounting holes of the opposite sidewalls adjoining the opening 60.

When the computer is powered up, the controlling module 28 receives the information transmitted from the SMBUS port of the motherboard. The controlling module 28 controls the motor 26 to rotate through a certain angle for driving the rack 30 to move, at the same time the rack 30 drives the shafts 242 of the slats 24 to rotate through a certain angle. Then the slats 24 are in an open position to expose the opening 60 in the front panel 10 for air flowing through, to dissipate heat produced by a plurality of computer components in the computer case. When the computer is off, the controlling module 28 controls the motor 26 to rotate through a certain angle in a reverse direction. The rack 30 moves back, and drives the slats 24 to a closed position to cover the opening 60 in the front panel 10 for preventing the dust from passing into the computer case.

The slats 24 of the motor-driven door 20 are controlled to expose or cover the opening 60 of the front panel 10 according to the computer being on or off. In other embodiments, the slats 24 of the motor-driven door 20 can be freely controlled to open or close according to a user's need by sending control information via the computer.

It is to be understood, however, that even though numerous characteristics and advantages of the preferred embodiments have been set forth in the foregoing description, together with details of the structures and functions of the embodiments, the disclosure is illustrative only, and changes may be made in detail, especially in matters of shape, size, equivalent material and arrangement of parts within the principles of the invention to the full extent indicated by the broad general meaning of the terms in which the appended claims are expressed.

What is claimed is:

1. A computer, comprising:
a front panel defining an opening; and
a door mounted to the front panel in alignment with the opening in the front panel, the door comprising a frame, a plurality of slats rotatably mounted to the frame, a motor mechanically connectable to the slats, and a controlling module controlling the motor to drive the slats to rotate for exposing or covering the opening in the front panel.

2. The computer as claimed in claim 1, wherein the controlling module receives information that the computer is powered on or off with the result of controlling the motor to drive the slats.

3. The computer as claimed in claim 1, wherein the frame comprises an upper wall, and a lower wall parallel to the upper wall, each of the slats comprises two shafts, a plurality of mounting holes are defined in the upper wall and the lower wall, corresponding to the shafts of the slats respectively.

4. The computer as claimed in claim 3, wherein the frame further comprises two sidewalls respectively connecting the upper wall and the lower wall.

5. The computer as claimed in claim 4, wherein a locking hole is defined in each of the sidewalls of the frame, the frame is mounted to the front panel by two fasteners extending through the corresponding locking holes of the frame to engage in the front panel.

6. The computer as claimed in claim 4, wherein the door further comprises a rack with a plurality of spaced teeth or notches located in the frame of the door, a plurality of first teeth is provided on one of the two shafts of each of the slats, a plurality of second teeth is provided on a shaft of the motor, the first teeth of each of the slats is positioned adjacent the lower wall, the first teeth of the slats and the second teeth of the motor are meshed with the teeth or notches of the rack.

7. The computer as claimed in claim 6, wherein a stop hole is defined in each of the sidewalls of the frame for guiding the rack to move therethrough and preventing the rack from disengaging from the first gears of the slats and the second gear of the motor.

8. A computer, comprising:
a computer case, the computer case comprising a front panel defining an opening; and
a door mounted in the computer case, the door comprising a plurality of slats rotatably positioned adjacent the opening, a motor, and a controlling module controlling the motor to drive the slats to rotate to expose the opening when the computer is on and to drive the slats to rotate to cover the opening when the computer is off.

9. The computer as claimed in claim 8, wherein the controlling module is connected to the computer via a cable, for receiving control information that the computer is powered on or off.

10. The computer as claimed in claim 8, wherein the door further comprises a frame, the frame comprises an upper wall, and a lower wall parallel to the upper wall, each of the slats comprises two shafts, a plurality of mounting holes are defined in the upper wall and the lower wall receiving the shafts of the slats respectively.

11. The computer as claimed in claim 10, wherein the frame further comprises sidewalls connecting the upper wall and the lower wall.

12. The computer as claimed in claim 11, wherein a locking hole is defined in each of the sidewalls of the frame, the frame is mounted to the front panel by two fasteners extending through the corresponding locking holes of the frame to engage in the front panel.

13. The computer as claimed in claim 1, wherein the door further comprises a rack located in the frame of the door, a first gear is set on one of the two shafts of each of the slats, a second gear is set on the motor, the first gears of the slats and the second gear of the motor are meshed with the rack.

14. The computer as claimed in claim 13, wherein a stop hole is defined in each of the sidewalls of the frame for guiding the rack to move therethrough and preventing the rack from disengaging from the first gears of the slats and the second gear of the motor.

15. A computer comprising:
a computer case comprising a front panel defining an opening;
a door mounted in the computer case, the door comprising a frame fixed at the front panel about the opening, a plurality of slats rotatably mounted to the frame;
a driving structure mechanically connected to the slats and configured to drive the slats to rotate, and;
a controlling module electrically connected to the driving structure and configured for receiving a singal from the computer to control the driving structure to drive the slats to rotate to expose the opening or to cover the opening.

16. The computer as claimed in claim 15, wherein the driving structure comprises a motor controlled by the controlling module and a rack slidably mounted to the frame and engaging with the slats, the motor being capable of driving the rack to slide along the frame in opposite directions to rotate the slats in opposite direction.

17. The computer as claimed in claim 16, wherein each of the slats comprises a shaft with first teeth formed thereon, the motor comprises another shaft with second teeth formed thereon, and the rack comprises a plurality of teeth or notches meshable with the first teeth and the second teeth.

18. The computer as claimed in claim 17, wherein the opening has a rectangular shape, the frame comprises four walls surrounding the opening, the slats are pivoted to a pair of the walls, and the rack is slidably attached to the other pair of the walls.

19. The computer as claimed in claim 17, wherein the controlling module controls the motor to drive the slats to rotate to expose the opening when the computer is powered on and to drive the slats to rotate to cover the opening when the computer is powered off.
